(19) United States
(12) Patent Application Publication
(10) Pub. No.: US 2005/0224108 A1
(43) Pub. Date: Oct. 13, 2005

(54) Enhanced photovoltaic module

(76) Inventor: Osbert H. Cheung, Concord, NC (US)

Correspondence Address: Bernard A. Chiama, Esq.;Apt. 420, 400 Avinger Lane, Davidson, NC, 28036, US

(21) Appl. No.: 10/822,877

(22) Filed: Apr. 13, 2004

(51) Int. Cl. H01L 31/00

(52) U.S. Cl. 136/251; 136/244

(57) ABSTRACT

A photovoltaic module and a method for its fabrication and installation on a support structure for the production of electrical current thereon is disclosed utilizing layers of materials which encapsulate one or more solar cells, and secure the same to a reinforcing sheet. Materials are utilized and manufacturing steps are practiced which maintain a long useful life of the module, will insure the stability for the layers to maintain their fixed positions during handling and installing of the module. Such materials are of less cost than those used in conventional modules, and the process steps are simple and easy to perform. The method permits the easy installation of the module on a supporting structure at room temperature prior to mounting the same at installation sites

### FIELD OF THE INVENTION

The present invention relates to the field of photovoltaic electrical generating modules of the type having a photovoltaic element encapsulating one or more solar cells adapted to generate electrical current in response to the impingement of sunlight thereon, and more particularly to modules, which include photovoltaic elements, arranged as panels for mounting. The modules are flexible, of low cost material, lightweight and may be easily customized and fabricated to size for most applications.

### BACKGROUND OF THE INVENTION

Photovoltaic technology is considered a promising, clean energy source due to the fact that it does not use such environmental unfriendly sources of combustion such as fossil fuels and nuclear energy, and to the fact its sole energizing medium is sunlight which Is unlimited in both availability and quantity. In recent years, photovoltaic devices in the form of solar cells have become increasingly popular for supplying limited electrical power for domestic use or electrical equipment in remote or mobile locations where conventional sources of electricity are not readily available, or in the interest of conserving electrical power. In more recent years, the use of photovoltaic energy has been seen as a viable replacement, although in a limit sense, for conventional production of electrical power as mentioned above, which rely upon the use of coal, oil and gas, and nuclear reactors. With regard to hydroelectric power generation, which may also be considered as a clean, environment friendly, energy source, geographical limitations and cost discount this source as viable for the purposes mentioned.

Prior art photovoltaic materials and processes are very extensive, and generally comprise layers of well known, commercially available materials arranged in stack formation to devise a photovoltaic element which encapsulates one or more or solar cells. The solar cells may be of a multi-crystalline or amorphous semiconductor, such as a silicone compound. Earlier versions of photovoltaic elements employed a thin glass plate cemented to the outermost light-sensitive surface of the solar cell of the element by a suitable sealant resin. The photovoltaic element generally comprises a stack of layers with glass as a covering layer and inert fluoropolymer as a back sheet to protect the element. However, while glass is impermeable to moisture and therefore is ideal as a weathering covering and as a rigid structural support for the solar cell, the use of glass plates present many inherent problems, most notably, that the glass plate cannot be bent. In addition, specifically tempered glass is heavy and expensive.

In the application for buildings, photovoltaic modules are placed either on the tops of buildings or mounted on surfaces of facades. For example, the glass type photovoltaic elements must be attached to the facade material with special rigid mounting brackets additional to the facade material itself. These arrangements not only increase the cost, but also add more weight on the building structure which must be reinforced to accommodate accordingly. In addition to being heavier, the applications of glass type photovoltaic elements tend to be limited by how these elements are manufactured through the production line. Since tempered glass has to be used as the cover substrate for the module, the size of the module has to be determined prior to the glass being tempered. Therefore, once the glass is tempered, the size for the photovoltaic module can not be changed. To make variable sizes of tempered glass for elements becomes very costly and time consuming. The high cost of making varieties of elements sizes is one of the main challenges of the photovoltaic industry. From this, it is apparent that the use of glass inhibits the most desirable capability of allowing large segments of photovoltaic materials, which are in large sheets, from being “cut to length or size”, so to speak, so as conform to various installation site, for example, multi-angled and sizes of building roof tops, automotive and marine vessel roof tops roadside support posts used for traffic light, etc.

Another limitation is that glass type photovoltaic elements allow very few applications which can be used in the installation associated with motion or as part of a moving body, such as vehicles, marine vessels, and portable electrical equipment. As will be apparent, the fragile nature of the glass plates increases the possibility of break down. A glass cover for photovoltaic elements not only functions as cover for protection, but also provides rigid structural support for the elements in a module. Photovoltaic modules without a glass cover, could cause potential damage on polycrystalline cells unless the solar cells are of the flexible type. Therefore, the module has to include a rigid back sheet to support the module from being distorted or bent if non-flexible type solar cells are used.

U.S. Pat. No. 6,553,729 discloses a method for adhering a rigid support sheet to photovoltaic elements. This patent discloses rubberized asphalt type adhesive for the application and is labeled as “Self-Adhesive Photovoltaic module.” The inherent potential problem with the use of asphalt and tar substrate materials in supporting modules on roof tops, etc., is that during hot sun exposure, the substrate will soften thereby may cause shifting, and in extreme cases, severe sliding movement, or even detachment of the module relative to their original, intended operative position. These prospects have restricted the installation of such module panels in the vertical, near vertical, or even to lesser degree orientations. To overcome these prospects, some installations have necessitated the use of superstructures designed and configured to support photovoltaic panels on roof structure utilizing hardware, metallic channels, fasteners, and the like, thus adding labor costs for mounting the panel and for the mounting hardware.

In further development of photovoltaic modules, as recited in many reports and publication, fluoropolymeric film has been used as module covering material for weathering and environmental protection. Most common fluoropolymer films being used are Tefzel, polyvinyl fluoride (PVF) and ethylene/tetrafluoroethylene (EFTE) coplymers. These types of film are lightweight, flexible and inexpensive, and show excellent results. U.S. Pat. Nos. 4,189,881, 5,474,620, 5,728,230 and 5,238,519 disclose a number of approaches to the fabrication of photovoltaic modules using fluoropolymer as cover material. Another copolymer film, in popular use, which functions as both an adhesive and a sealant is ethylene vinyl acetate (EVA) which will be cured and hardened after being heated at high temperature (i.e. 140 C). While forming strong bonds between the substrates, it also prevents moisture permeable to the photovoltaic cell. Other polylefin type resins include ethylene-methyl acrylate copolymer (EMA), ethylene-ethyl acrylate copolymer (EEA), and butyral resin, urethane resin, silicone, and the like.

The most common back protection layer has been the polyvinylidene fluoride film (PVF) sold under the Dupont Co. trademark, Tedlar which has been proven as one of the widely used protecting back films on photovoltaic modules because of its weathering and environment protecting features. However, as mentioned above, with mutilayer flexible polymer films stacking to protect solar cells, additional rigid reinforcing sheets will be needed to support such structure from distortion, if crystalline solar cells are used. It is well known that other materials are possible which can be applied for such reinforced sheet, such as steel, aluminum, FRP, and the like. Also several methods have been disclosed on how to bond the reinforced sheet to the photovoltaic element, that is, the solar cell with both fluoropolymer film and the Tedlar film adhering by EVA.

Two processes for applying adhesives to substrates are currently in practice: one utilizing high temperature adhesives and the other low temperature adhesives. In the former process, the high temperature requires the use of EVA or similar polymeric material which will form bonds during the heating process, as disclosed in U.S. Pat. No. 5,728,230. In U.S. Pat. No. 5,238,519 the method of using a reinforced plate such as fiberglass, aluminum or galvanized steel is disclosed. The method of bonding the Tedlar layer and the reinforced plate is accomplished by adding a EVA layer between them, and then, heating up to high temperature.

The problem for the high temperature method is that the reinforced material must also be tolerated at such high temperature during the adhering process. Because of this heating unfortunately, many rigid, lightweight, low cost reinforcing materials can not be used in this method. Only a few rigid materials can be qualified for this method, such as, aluminum, steel, fiberglass reinforced plastics (FRP), carbon fiber, and the like. Alternatively, the low temperature adhesive method is able to adhere a photovoltaic device to a reinforcing plate at room temperature, as disclosed in U.S. Pat. No. 6,553,729. However, this patent discloses rubberized asphalt type adhesive for such application, which is labeled as “Self-Adhesive Photovoltaic Module”. As previously mentioned, the problem with this application is that asphalt can become soft at high temperature and brittle at cold temperature. This material is only suitable on flat roofs, or on roofs with certain degree slope relative to the horizontal plane. Otherwise, when mounted in vertical or near vertical orientation, it may present potential problems for the possibility of sliding or even dislodgement of the module.

### SUMMARY OF THE INVENTION

The present invention has been particularly devised to overcome the limitations and problems described in the foregoing, such limitations and problems involving: 1) the use of glass as one of the layers in a photovoltaic module concerning the lack of the capability for “on-the-spot” customized installation design, flexibility, cost and weight; 2) the conventional process of employing high temperatures in fabricating the adhesion of the various layers; which make up the photovoltaic module, and, 3) the cumbersome and costly hardware generally used for mounting a module upon a final supporting structure at the installation site.

The configuration of the present invention comprises a new combination of layers of protective and adhesive materials which, will 1) insure the efficient transmission of sunlight upon one or more solar cells encapsulated in the module, 2) will possess the ability to remain in their originally processed positions throughout the life of the module, and 3) be economical in manufacture and installation. The configuration also includes a truly self-adhesive material of the peel and seal type which, will permit a module to be applied to a reinforced back sheet or panel mounted on a building or vehicle supporting structure at ambient temperature and slight hand pressure. The invention is also directed a new method for fabrication and installing a photovoltaic module which will insure that the same will not shift or slide relative to its supporting structure upon which the module is installed, and that the layers comprising the module will not separate during handling, bending or rolling or during heating after installation due to high ambient temperatures.

### BRIEF DESCRIPTION OF THE DRAWINGS

FIG. 1 is a cross-sectional view of a portion of the photovoltaic module device in accordance with present invention; with the parts thereof in spaced separation for better illustration; and

FIG. 2 is a perspective view of a plurality of modules of FIG. 1, made in accordance with invention, as applied to a building façade.

### DETAILED DESCRIPTION OF THE INVENTION

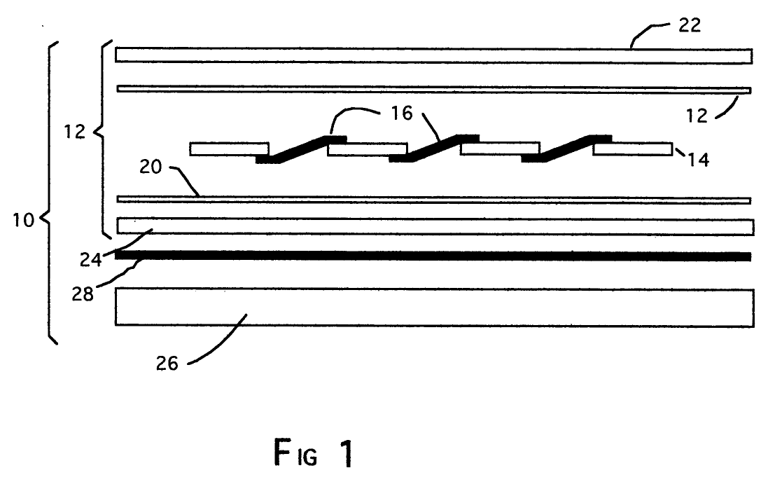

As shown in FIG. 1, a photovoltaic module, generally indicated by the reference numeral 10 and devised in accordance with the present invention, includes a photovoltaic element 12 having a photovoltaic device comprising a plurality of solar cells 12, each of which may be a monocrystalline cell, multicrystalline cell, amorphorus silicone photovoltaic cell, or a compound semiconductor photovoltaic cell. The preferred solar cells in the present invention are of the multicrystalline type since it is of the least cost, and is able to sustain a longer period in which to generate electricity. The solar cells 14 are connected by suitable electrical conductors 16 which, are connected to a central electrical network, not forming a part of the invention. The cells are encapsulated within the element by a set of layers 18, 20, to be described herewith. The first or upper layer 18 is adhesively arranged on the surfaces of the solar cells which directly receive sunlight for producing electrical current, and the lower or bottom layer 20 is similar to the layer 18 being adhesively arranged on the surfaces of the cells opposite the surfaces receiving sunrays. For the present invention, the layers 16, 18 are preferably made from the copolymer film ethylene vinyl acetate (EVA). Other polyolfin types may be employed for the layers 16, 18, such as ethylene-methyl acrylate copolymer (FMA), silicone resin, and the like.

A protective or cover layer 22, mounted exteriorly of the combination of the solar cells and the layers 18, 20, and applied to the surface of the upper layer 18 which faces the sun, serves to protect the module 10 from exterior contaminants, weather conditions and physically applied damage. The protective layer 22 may consist of a fluoropolymer material, preferably Tefzel, polyvinyl fluride (PVF) or ethylene/tetrafluoroethylene copolymer (EFTE). Both layers 18, 20 while encapsulating the solar cells 14, also serve as a sealant and an adhesive applied on either side of the solar cells 14, respectively, with the protective layer 22 adhering to the layer 18.

In the element stack 12, the lower adhesive layer 20 of EVA is also attached to a lower layer 24, which is a back protection sheet or layer made of a material that is very critical in maintaining the structural stability of the element 12. In the field of producing photovoltaic modules, a protection layer made of a polyvinyl fluoropolymer film, or Tedlar. has been one of the most widely used protecting back films for protecting photovoltaic modules because of its excellent weathering and environment protecting features. This material is resistant to almost all chemicals and other hazards including UV radiation. However, the polyvinyl fluoropolymer type material is very difficult to bond to other materials. In most cases, to bond Tedlar film, requires either high temperatures during curing conditions, or many process steps.

In accordance with the invention, the layer 24 is a protecting, insulating film, which has superior adhesion properties for bonding to other materials, and cost less than the conventional polyvinyl fluoropolymer type materials. For this purpose, the layer 24 in the present invention utilizes, as the preferred material, the polyester type film, polyethylene terephthalate (PET), which has superior adhesion and protection properties than other counterpart materials found in the market and in the above cited art These superior properties are essential in maintaining and insuring a long life for photovoltaic modules. This material, as compared to Tedlar film, has better adhesion properties with respect to bonding with other materials, and also serves as an insulating film as it provides excellent electric insulation for the solar cells 14. Particularly, the layer 24 can form a strong bond with a reinforcing support sheet at room temperature, as will be described below. For another effective PET material, the layer 24 may utilize the polyester Melinex 6248/6249 one of the Dupont/Teijin films, which has a breakdown voltage of at least 10 kV. It has demonstrated physical and chemical resistant properties similar to Tedlar film, but with less cost.

As shown in FIG. 1, the photovoltaic element 12 is formed by the combination of the cover sheet 22, the solar cells 14 encapsulated between the sealants/adhesives 18, 20, and the insulating sheet 24. The photovoltaic element 12 is secured to a reinforced support sheet 26 by utilizing a peel and seal adhesive tape 28 thereby completing the structure of the module 10. The support sheet serves to maintain the photovoltaic element stack free from distortion. The reinforced support sheet 26 is preferably made from aluminum composite material (ACM), which is generally used for building facades. In enhancing the present invention, the ACM material utilized is sold, for example, under the trademark Alucobond, manufactured by Alcan Composite Corp, and under the trademark Alpolic, manufactured by Mitsubichi Chemical Industry, Ltd. The ACM panels are used on building facades and have proven to stand all weather conditions.

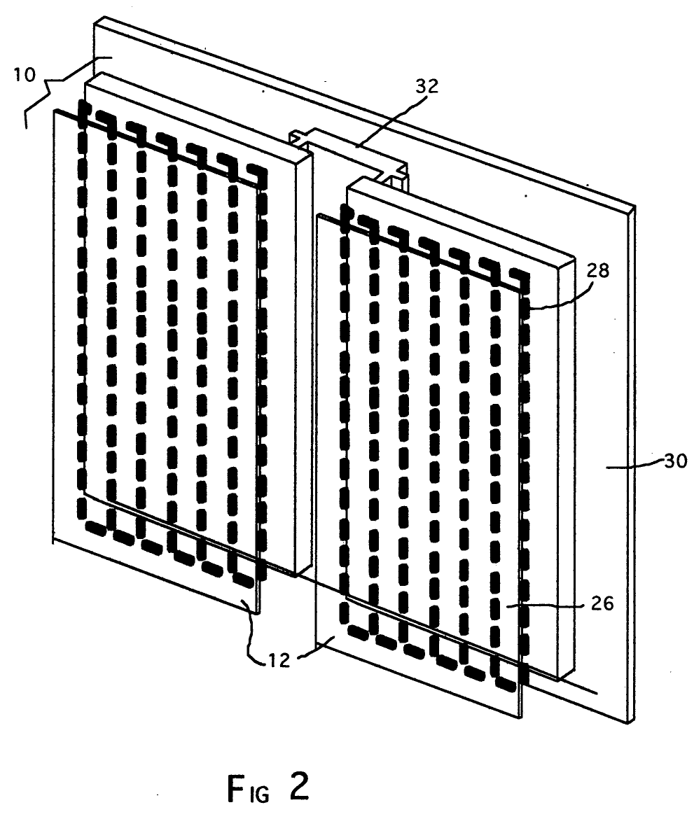

As shown in FIG. 2, a plurality of photovoltaic modules 10 are shown attached to a roof substrate 30, by attaching the respective sheets 26 thereto, utilizing suitable brackets 32, as in a normal installation arrangement. The structure 30 may be the outer material of a building roof, a vehicle roof top, a roadside post, etc., upon which one more modules 10 can be mounted for use, and in any angular plane.

In the fabrication of a photovoltaic element 12 in accordance with the present invention, and the mounting thereof as a photovoltaic element 12 to a support structure for operation and use, a two step process is involved: 1) the element 12 is assembled by stacking the cover layer 22 of Tefzel or EFTE upon the adhesive layers 18, 20 with the solar cells 14 therebetween, the layers 18, 20 comprising EVA material alone, or with scrim, which is a glass fiber layer made of woven or non-woven fiber material. The EVA or EVA/scrim layers with the solar cells between them are melted by heating and cross linked or cured to form an encapsulant. In continuing the assembly of the element 12, the insulating layer 24 is attached to the layer 20 to complete the fabrication of the photovoltaic element 12.

In step 2) of the process, the element 12 is bonded to the reinforced back sheet 26 with the adhesive layer 28 therebetween. The layer 28 is a pressure sensitive adhesive (PSA) tape, for example, the adhesive transfer tape 4920, an acrylic resin type adhesive, of the peel and seal type, from the VHB series sold by the 3M Corp. The layer 28 may also may be one selected from the group of acrylic adhesives, silicone adhesives, urethane adhesives and epoxy adhesives, and preferably has a thickness range between 0.03 and 3.0 mm. This step in the process is preformed at room temperature with little pressure, such as finger press to complete. The VHB series tape has been widely used in the building industry as alternatives to rivets, spot welding, screws and other permanent fasteners, as these tapes have proven to be cost effective with long lasting bonding strengths. The invention includes but is not limited to VHB double coated acrylic foam tapes and adhesive transfer tapes. bonding thereto, and then peels the protective liner from the other side of the tape and bonds the same by finger pressure to the reinforced back sheet 26, all at ambient temperature. As an alternative, the tape 28 may be attached to the insulating layer 24 while still at the installation site, and the installer need only to remove the remaining protection tab from the tape 28 for attachment to the support panel structure 26. In essence, the invention allows a photovoltaic element to be fabricated at an assembly plant or the like, to correspond to the required size for final use in ready to use condition, and be transported to an installation site. Actual installation merely requires the installer to position the photovoltaic element at the selected position relative to a support panel there at, and then utilize the self-adhesive tape at that position, as aforesaid.

From the foregoing, it will be appreciated that the invention enhances the art of photovoltaic generating systems by combining selected materials in a manner wherein photovoltaic modules can be produced at low cost, be lightweight, have self-adhesive capability, and to be applicable to final supporting surfaces having any angular orientation. It will be appreciated that the inventive process enables a photovoltaic element to be fabricated at the manufacturing level, to be customized to size and shape while still at the manufacturing level so as to coincide with the size and shape of the final supporting structure at the installation site, and to be finally installed by merely exposing the protecting tabs of a transfer tape and applying the module to the final supporting substrate for use. It will also be appreciated that the layers of selected materials and the manner in which they are fabricated will insure that the layers will not slip or become separated during handling and after many years of use, and that the module will remain at installed position throughout its life.

1. A photovoltaic module adapted for attachment to supporting structure on buildings, vehicles, or other fixed or mobile structure, comprising a photovoltaic element including one or more photovoltaic solar cells each with one side arranged to receive sun rays thereon for generating electrical current in response to sun light impinging thereon and another side facing the support structure, said solar cell(s) being encapsulated between sealant, adhesive layers to form the photovoltaic element, said photovoltaic element including a back protection layer made from polyester type film, a reinforcing support sheet, and an adhesive material being adhesively attached between said reinforcing support sheet and said protection layer, said adhesive material being adapted to be applied to said reinforcing support sheet during final installation at room temperature.

2. The photovoltaic module as defined in claim 1, wherein the adhesive in said adhesive material is ethylene vinyl acetate.

3. The photovoltaic module as defined in claim 1, wherein the adhesive in said adhesive material is at least one selected from the group of acrylic adhesive, silicone adhesives, urethane adhesive and epoxy adhesive.

4. The photovoltaic module as defined in claim 1, wherein the thickness of said adhesive material ranges between 0.03 and 3.0 mm.

5. The photovoltaic module as defined in claim 4, wherein the dielectric breakdown voltage of said protection film is at least 10 kV.

6. The photovoltaic module as defined in claim 1, wherein said insulating film is one selected from polyester, polyethylene terephthalate, nylon and the like.

7. The photovoltaic module as defined in claim 1, wherein said reinforcing sheet is made of one selected from steel, plastic sheet, aluminum composite material (ACM), glass, fiberglass reinforced panel

8. The method for producing a photovoltaic element having one or more solar cells and applying the same to a reinforcing support sheet with the solar cell(s) facing sunlight for the impingement of sunlight thereon, comprising the steps of stacking in order: a cover face plate having an adhesive layer provided on one surface thereof being applied to the side(s) of the solar cell(s) facing sunlight, an insulating protection layer with adhesive material applied between the same and the other side of the solar cell(s), laminating said cover plate and said protection layer with said solar cells therebetween, and bonding said reinforcing sheet to said protection layer with adhesive material at room temperature.

9. The method as defined in claim 8, wherein said insulating layer is one selected from polyester, polyethylene teraphthalate, and nylon.
